(19) United States
(12) Patent Application Publication
(10) Pub. No.: US 2026/0173733 A1
(43) Pub. Date: Jun. 18, 2026

(54) Display Substrate and Manufacturing Method Thereof, Display Apparatus, and Method for Reducing Driving Voltage of Display Substrate

(71) Applicants: Chengdu BOE Optoelectronics Technology Co., Ltd., Chengdu, Sichuan (CN); BOE Technology Group Co., Ltd., Beijing (CN)

(72) Inventors: Huan WU, Beijing (CN); Rongrong GAO, Beijing (CN); Meishan XU, Beijing (CN); Yan YANG, Beijing (CN); Yicheng FAN, Beijing (CN)

(21) Appl. No.: 18/710,631

(22) PCT Filed: May 15, 2023
(86) PCT No.: PCT/CN2023/094330

§ 371 Date: May 16, 2024

(51) Int. Cl. H10K 59/80; H10K 59/12; H10K 59/35; H10K 101/40

(52) U.S. Cl. CPC H10K 59/876; H10K 59/1201; H10K 59/35; H10K 2101/40

(57) ABSTRACT

A display substrate and a manufacturing method thereof, a display apparatus, and a method for reducing driving voltage of a display substrate. The display substrate comprises a red sub-pixel, further comprises: a first electrode layer (10), a second electrode layer (50), a plurality of light emitting units disposed between the first electrode layer (10) and the second electrode layer (50) and connected in series, and a charge generation layer disposed between two adjacent light emitting units. A microcavity is formed between the first electrode layer (10) and the second electrode layer (50). The light emitting units comprise a first hole transport layer (21), a second hole transport layer (22) and an emitting layer. The emitting layer comprises a red light emitting layer located at the red sub-pixel. At least one of the light emitting units further comprises a red light emitting auxiliary layer located at the red sub-pixel.

### CROSS-REFERENCE TO RELATED APPLICATION

This application is a U.S. National Phase Entry of International Application No. PCT/CN2023/094330, having an international filing date of May 15, 2023, the content of which is hereby incorporated into this application by reference.

### TECHNICAL FIELD

The embodiments of the present disclosure relate to, but are not limited to, the field of display technology, and in particular to a display substrate and a display apparatus, and a method for reducing the driving voltage of the display substrate.

### BACKGROUND

In the application field of organic semiconductor technology, the technology in Organic Light Emitting Device (OLED) has been successfully applied in commercial flat panel display and lighting industries. OLED has the characteristics of self-luminescence, no need for backlight, thin panel thickness and light weight. Meanwhile, OLED also has the advantages of wide viewing angle, large contrast, fast respond time, wide working temperature range and flexibility. Among them, Tandem OLED devices play an important role in the field of OLED display and lighting.

### SUMMARY

The following is a summary of subject matters described herein in detail. The summary is not intended to limit the protection scope of the present disclosure.

The embodiments of the present disclosure provides a display substrate, comprising a red sub-pixel, and further comprising: a first electrode layer, a second electrode layer, a plurality of light emitting units disposed between the first electrode layer and the second electrode layer and connected in series, and a charge generation layer disposed between two adjacent light emitting units. A microcavity is formed between the first electrode layer and the second electrode layer. The light emitting units include a first hole transport layer, a second hole transport layer and an emitting layer. The emitting layer includes a red light emitting layer located at the red sub-pixel. At least one of the light emitting units further includes a red light emitting auxiliary layer located at the red sub-pixel. The red light emitting auxiliary layer is disposed between the red light emitting layer and the second hole transport layer. The red light emitting auxiliary layer includes a hole transport material.

In the display substrate, a thickness of each of the red light emitting layers is 8% to 16% of a thickness of the microcavity.

In an exemplary embodiment of the present disclosure, the thickness of each of the red light emitting layers may be 8% to 10% of the thickness of the microcavity.

In an exemplary embodiment of the present disclosure, the thickness of each of the red light emitting auxiliary layers may be 1% to 5% of the thickness of the microcavity.

In an exemplary embodiment of the present disclosure, the thickness of each of the red light emitting auxiliary layers may be 3% to 5% of the thickness of the microcavity.

In an exemplary embodiment of the present disclosure, a total thickness of the red light emitting layer and the red light emitting auxiliary layer in one light emitting unit may be 9% to 17% of the thickness of the microcavity.

In an exemplary embodiment of the present disclosure, the second hole transport layer and the red light emitting auxiliary layer can satisfy the following conditions:

$${µ}_{HTL - 3} - {µ}_{HTL - 2} \geq 1 \times 1 {0}^{- 1} @ 5000 {V}^{1 / 2} {m}^{1 / 2} ;$$

wherein μ_{HTL-3} is the mobility of the red light emitting auxiliary layer at 5000V^{1/2}m^{1/2};
μ_{HTL-2} is the mobility of the second hole transport layer at 5000V^{1/2}m^{1/2}.

In an exemplary embodiment of the present disclosure, the red light emitting auxiliary layer and the red light emitting layer can satisfy the following conditions:

$$\vert {n}_{REML} - {n}_{HTL - 3} \vert < 0.1 ;$$

wherein n_{REML} is the refractive index of the red light emitting layer;
   n_{HTL-3} is the refractive index of the red light emitting auxiliary layer.

In an exemplary embodiment of the present disclosure, the red light emitting auxiliary layer and the red light emitting layer can satisfy the following conditions:

$$3 eV \leq \vert {HOMO}_{HTL - 3} \vert - \vert {LUMO}_{HTL - 3} \vert \leq 3.4 eV ;$$

$$\vert {HOMO}_{REML} \vert - \vert {HOMO}_{HTL - 3} \vert < 0.2 eV ;$$

$$\vert {LUMO}_{REML} \vert - \vert LUM {O}_{HTL - 3} \vert < 0.2 eV ;$$

wherein HOMO_{HTL-3} is the highest occupied molecular orbital energy level of the red light emitting auxiliary layer;
   LUMO_{HTL-3} is the lowest unoccupied molecular orbital energy level of the red light emitting auxiliary layer;
   HOMO_{REML} is the highest occupied molecular orbital energy level of the red light emitting layer;
   LUMO_{REML} is the lowest unoccupied molecular orbital energy level of the red light emitting layer.

In an exemplary embodiment of the present disclosure, the first hole transport layer, the second hole transport layer, the red light emitting auxiliary layer and the red light emitting layer can satisfy the following conditions:

$${T}_{HTL - 3} > {T}_{HTL - 2} ;$$

$${T}_{HTL - 3} < {T}_{HTL - 1} ;$$

$${T}_{HTL - 3} + {T}_{HTL - 2} \geq {T}_{HTL - 1} ;$$

$${T}_{HTL - 3} < {T}_{REML} ;$$

wherein T_{HIL-1} is a thickness of the first hole transport layer;
   T_{HTL-2} is a thickness of the second hole transport layer;
   T_{HTL-3} is a thickness of the red light emitting auxiliary layer;
   T_{REML} is a thickness of the red light emitting layer.

In an exemplary embodiment of the present disclosure, the thickness of each of the red light emitting layers may be 30 nm to 50 nm, and the thickness of each of the red light emitting auxiliary layers may be 10 nm to 25 nm.

In an exemplary embodiment of the present disclosure, the display substrate may further include a green sub-pixel and a blue sub-pixel, the emitting layer further includes a green light emitting layer and a blue light emitting layer respectively located at the green sub-pixel and the blue sub-pixel, and at least one of the light emitting units may further include any one or more of a green light emitting auxiliary layer located at the green sub-pixel and a blue light emitting auxiliary layer located at the blue sub-pixel. The green light emitting auxiliary layer includes a hole transport material, and the blue light emitting auxiliary layer includes a hole transport material.

In an exemplary embodiment of the present disclosure, the red light emitting auxiliary layer, the green light emitting layer, and the blue light emitting layer can satisfy the following conditions:

$$\vert {HOMO}_{GEML} \vert - \vert {HOMO}_{HTL - 3} \vert \geq 0.2 eV ;$$

$$\vert {HOMO}_{BEML} \vert - \vert {HOMO}_{HTL - 3} \vert \geq 0.2 eV ;$$

wherein HOMO_{HTL-3} is the highest occupied molecular orbital energy level of the red light emitting auxiliary layer;
HOMO_{GEML} is the highest occupied molecular orbital energy level of the green light emitting layer;
HOMO_{BEML} is the highest occupied molecular orbital energy level of the blue light emitting layer.

In an exemplary embodiment of the present disclosure, the hole transport materials in the red light emitting auxiliary layer, the green light emitting auxiliary layer, and the blue light emitting auxiliary layer may be each independently selected from any one or more of an arylamine-based hole transport material, a carbazole-based hole transport material, and a dimethylfluorene-based hole transport material.

In an exemplary embodiment of the present disclosure, the red light emitting layer may include a red host material and a red guest material, and a doping ratio of the red guest material is 1% to 5%.

In an exemplary embodiment of the present disclosure, the red host material may include any one or more of a DCM-series red luminescent material, and the red guest material may include any one or more of a metal complex-based red luminescent material.

In an exemplary embodiment of the present disclosure, the green light emitting layer may include a green host material and a green guest material, and a doping ratio of the green guest material may be 5% to 15%.

In an exemplary embodiment of the present disclosure, the green host material may include any one or more of a coumarin dye, a quinacridone derivative-based green luminescent material, a polycyclic aromatic hydrocarbon-based green luminescent material, a diamine anthracene derivative-based green luminescent material, and a carbazole derivative-based green luminescent material, and the green guest material may include any one or more of a metal complex-based green luminescent material.

In an exemplary embodiment of the present disclosure, the blue light emitting layer may include a blue host material and a blue guest material, and a doping ratio of the blue guest material is 1% to 5%.

In an exemplary embodiment of the present disclosure, the blue host material may include any one or more of a pyrene derivative-based blue luminescent material, an anthracene derivative-based blue luminescent material, a fluorene derivative-based blue luminescent material, a perylene derivative-based blue luminescent material, and a styrylamine derivative-based blue luminescent material, and the blue guest material may include any one or more of a metal complex-based blue luminescent material.

An embodiment of the present disclosure further provides a display apparatus, including the display substrate as provided in the above embodiment of the present disclosure.

An embodiment of the present disclosure further provides a method for manufacturing the display substrate as provided in the above embodiment of the present disclosure. The manufacturing method includes the following steps:
forming a first electrode layer on a side of a substrate;
forming a first hole transport layer and a second hole transport layer sequentially on a side of the first electrode layer away from the substrate;
forming a red light emitting auxiliary layer located at a red sub-pixel through an evaporation method on a side of the second hole transport layer away from the substrate;
forming a red light emitting layer located at a red sub-pixel through an evaporation method on a side of the red light emitting auxiliary layer away from the substrate; and forming a green light emitting layer and a blue light emitting layer respectively located at a green sub-pixel and a blue sub-pixel on a side of the second hole transport layer away from the substrate, wherein an emitting layer is constituted by the red light emitting layer, the green light emitting layer and the blue light emitting layer, and one light emitting unit is constituted by the emitting layer, the red light emitting auxiliary layer, the first hole transport layer and the second hole transport layer;
forming a charge generation layer on a side of the light emitting unit away from the substrate;
forming at least one light emitting unit on a side of the charge generation layer away from the substrate, and forming a charge generation layer between two adjacent light emitting units; and
forming a second electrode layer.

The embodiment of the disclosure also provides a method for reducing a driving voltage of a display substrate. The display substrate includes a red sub-pixel and further includes: a first electrode layer, a second electrode layer, a plurality of light emitting units disposed between the first electrode layer and the second electrode layer and connected in series, and a charge generation layer disposed between two adjacent light emitting units. A microcavity is formed between the first electrode layer and the second electrode layer. The light emitting units include a first hole transport layer, a second hole transport layer and an emitting layer. The emitting layer includes a red light emitting layer located at the red sub-pixel.

The method for reducing the driving voltage of the display substrate includes: forming a red light emitting auxiliary layer located at the red sub-pixel by adopting a hole transport material between the red light emitting layer and the second hole transport layer, and the thickness of the red light emitting layer is 8% to 16% of the thickness of the microcavity, the thickness of the red light emitting auxiliary layer is 1% to 5% of the thickness of the microcavity, and a total thickness of the red light emitting layer and the red light emitting auxiliary layer in one light emitting unit is 9% to 17% of the thickness of the microcavity.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display substrate provided by an exemplary embodiment of the present disclosure.

FIG. 2 is a schematic diagram of a structure of another display substrate provided by an exemplary embodiment of the present disclosure.

FIG. 3 is a schematic diagram of a structure of yet another display substrate provided by an exemplary embodiment of the present disclosure.

FIG. 4 is a schematic diagram of a structure of yet another display substrate provided by an exemplary embodiment of the present disclosure.

Meanings of reference signs in the accompanying drawings are as follows:

10—First Electrode Layer; 20—First Light Emitting Unit; 21—First Hole Transport Layer; 22—Second Hole Transport Layer; 23—First Red Light Emitting Auxiliary Layer; 24—First Emitting Layer; 241—First Red Light Emitting Layer; 242—First Green Light Emitting Layer; 243—First Blue Light Emitting Layer; 25—First Green Light Emitting Auxiliary Layer; 26—First Blue Light Emitting Auxiliary Layer; 27—First Hole Block Layer; 30—First Charge Generation Layer; 40—Second Light Emitting Unit; 41—Third Hole Transport Layer; 42—Fourth Hole Transport Layer; 43—Second Red Light Emitting Auxiliary Layer; 44—Second Emitting Layer; 441—Second Red Light Emitting Layer; 442—Second Green Light Emitting Layer; 443—Second Blue Light Emitting Layer; 45—Second Hole Block Layer; 50—Second Electrode Layer; 60—Third Light Emitting Unit; 61—Fifth Hole Transport Layer; 62—Sixth Hole Transport Layer; 63—Third Red Light Emitting Auxiliary Layer; 64—Third Light Emitting Layer; 641—Third Red Light Emitting Layer; 642—Third Green Light Emitting Layer; 643—Third Blue Light Emitting Layer; 70—Second Charge Generation Layer; 80—Hole Injection Layer.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description and simplification of the description only, but do not indicate or imply that the referred device or element must have a particular orientation, be constructed and operate in a particular orientation, and therefore cannot be construed as limitations on the present disclosure. The positional relationships between the constituent elements may be changed as appropriate according to a direction according to which each constituent element is described. Therefore, it is not limited to the words and expressions described in the present disclosure, and may be appropriately replaced according to situations.

In the present disclosure, the terms “mounted”, “connected” and “connection” are to be understood broadly, unless otherwise expressly specified and defined. For example, a connection may be fixed connection, or a detachable connection, or an integral connection; it may be a mechanical connection or an electrical connection; it may be a direct connection, or an indirect connection through middleware, or internal communication inside two elements. For those of ordinary skills in the art, specific meanings of the above terms in the present disclosure may be understood according to actual situations.

In the present disclosure, “electric connection” includes a case where constituent elements are connected through an element with a certain electrical effect. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

Ordinal numerals such as “first” and “second” in the present disclosure are provided to avoid confusion between constituent elements, but do not indicate any order, quantity or importance.

In the present disclosure, “film” and “layer” are interchangeable. For example, an “emitting layer” may be replaced with a “light emitting film” sometimes.

The light emitting of an organic light emitting device (OLED) is driven by electric current. Under the same current density, the light emitting brightness of a Tandem OLED composed of n identical light emitting units is n times of that of a traditional OLED composed of single light emitting unit, and therefore, the current efficiency of a Tandem OLED is n times of that of a traditional OLED. However, the driving voltage of a Tandem OLED is n times of that of a traditional OLED, and therefore, the power efficiencies of them are similar in theory. In addition, OLED display and lighting equipment work at a certain brightness. Under the same light emitting brightness, the current density driving a Tandem OLED is 1/n of that of a traditional OLED. The higher the current density of an OLED is, the faster the aging and the shorter the service life of the device are. Therefore, the service life of a Tandem OLED is longer than that of a traditional OLED.

The embodiments of the present disclosure provides a display substrate, comprising a red sub-pixel, and further comprising: a first electrode layer, a second electrode layer, a plurality of light emitting units disposed between the first electrode layer and the second electrode layer and connected in series, and a charge generation layer (CGL) disposed between two adjacent light emitting units. A microcavity is formed between the first electrode layer and the second electrode layer. The light emitting units include a first hole transport layer (HTL), a second hole transport layer and an emitting layer (EML). The emitting layer includes a red light emitting layer located at the red sub-pixel. At least one of the light emitting units further includes a red light emitting auxiliary layer located at the red sub-pixel. The red light emitting auxiliary layer is disposed between the red light emitting layer and the second hole transport layer. The red light emitting auxiliary layer includes a hole transport material.

In the display substrate, a thickness of each of the red light emitting layers is 8% to 16% of a thickness of the microcavity.

In the current OLED display substrate, the thickness of each of the red light emitting layer is about 9% to 20% of the thickness of the microcavity between the first electrode layer and the second electrode layer. In the display substrate of an embodiment of the present disclosure, a red light emitting auxiliary layer including a hole transport material is disposed on the red light emitting layer side, and the thickness of each of the red light emitting layer is reduced to be 8% to 16% of the thickness of the microcavity. Therefore, the red light emitting auxiliary layer replaces the red light emitting layer having a certain thickness, which can reduce the driving voltage of the display substrate.

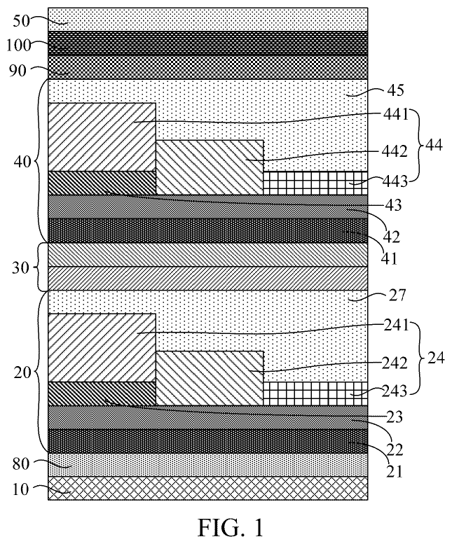

FIG. 1 is a schematic diagram of a structure of a display substrate provided by an exemplary embodiment of the present disclosure. The display substrate includes a red sub-pixel, a green sub-pixel and a blue sub-pixel; as shown in FIG. 1, the display substrate further includes: a first electrode layer 10, a first light emitting unit 20, a first charge generation layer 30, a second light emitting unit 40, and a second electrode layer 50.

The first electrode layer 10 is an anode layer and the second electrode layer 50 is a cathode layer, or, the first electrode layer 10 is a cathode layer and the second electrode layer 50 is an anode layer. A microcavity is formed between the first electrode layer 10 and the second electrode layer 50, and the thickness of the microcavity is T.

The first light emitting unit 20 is disposed on the first electrode layer 10 side. The first light emitting unit 20 includes a first hole transport layer 21 disposed on the first electrode layer 10 side, a second hole transport layer 22 disposed on a side of the first hole transport layer 21 away from the first electrode layer 10, and a first red light emitting auxiliary layer 23 and a first emitting layer 24 disposed on a side of the second hole transport layer 22 away from the first electrode layer 10. The first emitting layer 24 includes a first red light emitting layer 241 located at a red sub-pixel, a first green light emitting layer 242 located at a green sub-pixel, and a first blue light emitting layer 243 located at a blue sub-pixel. The first red light emitting auxiliary layer 23 is located at the red sub-pixel and between the second hole transport layer 22 and the first red light emitting layer 241. The first red light emitting auxiliary layer 23 includes a hole transport material having a thickness of 8% to 16% of the thickness of the microcavity.

The first charge generation layer 30 is disposed on a side of the first light emitting unit 20 away from the first electrode layer 10, for connecting the first light emitting unit 20 and the second light emitting unit 40 and generating carriers.

The second light emitting unit 40 is disposed on a side of the first charge generation layer 30 away from the first electrode layer 10. The second light emitting unit 40 includes a third hole transport layer 41 disposed on a side of the first charge generation layer 30 away from the first electrode layer 10, a fourth hole transport layer 42 disposed on a side of the third hole transport layer 41 away from the first electrode layer 10, and a second red light emitting auxiliary layer 43 and a second emitting layer 44 disposed on a side of the fourth hole transport layer 42 away from the first electrode layer 10. The second emitting layer 44 includes a second red light emitting layer 441 located at a red sub-pixel, a second green light emitting layer 442 located at a green sub-pixel, and a second blue light emitting layer 443 located at a blue sub-pixel. The second red light emitting auxiliary layer 43 is located at the red sub-pixel and between the fourth hole transport layer 42 and the second red light emitting layer 441. The second red light emitting auxiliary layer 43 includes a hole transport material having a thickness of 8% to 16% of the thickness of the microcavity.

In the display substrate shown in FIG. 1, the number of light emitting units is 2 and the red sub-pixel of each light emitting unit is provided with a red light emitting auxiliary layer.

In other exemplary embodiments, a red light emitting auxiliary layer may be disposed at a red sub-pixel of only one light emitting unit to replace the red light emitting layer having a certain thickness, and the driving voltage of the display substrate may also be effectively reduced. But all of the red sub-pixels being provided with red light emitting auxiliary layers will be beneficial to the reduction of the driving voltage of the display substrate to a greater extent.

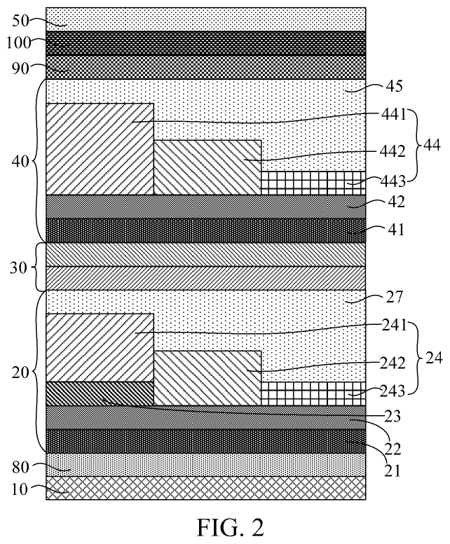

FIG. 2 is a schematic diagram of a structure of another display substrate provided by an exemplary embodiment of the present disclosure. In the display substrate shown in FIG. 2, two light emitting units: a first light emitting unit 20 and a second light emitting unit 40, disposed in series, are included, but only the red sub-pixel of the first light emitting unit 20 is provided with a red light emitting auxiliary layer, and the driving voltage of the display substrate is lower.

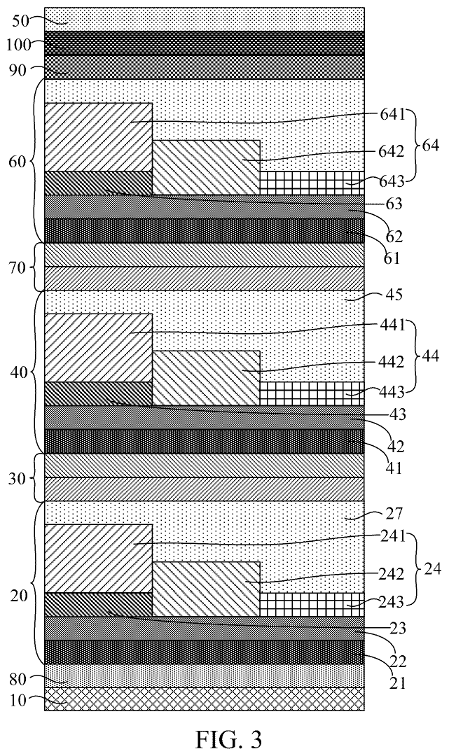

FIG. 3 is a schematic diagram of a structure of yet another display substrate provided by an exemplary embodiment of the present disclosure. In the display substrate shown in FIG. 3, three light emitting units: a first light emitting unit 20, a second light emitting unit 40, and a third light emitting unit 60, disposed in series, are included, and a second charge generation layer 70 is disposed between the second light emitting unit 40 and the third light emitting unit 60.

The third light emitting unit 60 is disposed on a side of the second charge generation layer 70 away from the first electrode layer 10. The third light emitting unit 60 includes a fifth hole transport layer 61 disposed on a side of the second charge generation layer 70 away from the first electrode layer 10, a sixth hole transport layer 62 disposed on a side of the fifth hole transport layer 61 away from the first electrode layer 10, and a third red light emitting auxiliary layer 63 and a third light emitting layer 64 disposed on a side of the sixth hole transport layer 62 away from the first electrode layer 10. The third light emitting layer 64 includes a third red light emitting layer 641 located at a red sub-pixel, a third green light emitting layer 642 located at a green sub-pixel, a third blue light emitting layer 643 located at a blue sub-pixel. The third red light emitting auxiliary layer 63 is located at the red sub-pixel and between the sixth hole transport layer 62 and the third red light emitting layer 641. The third red light emitting auxiliary layer 63 includes a hole transport material having a thickness of 8% to 16% of the thickness of the microcavity. Other structures are the same as those of the display substrate shown in FIG. 1.

In an exemplary embodiment of the present disclosure, the thickness of each of the red light emitting layers may be 8%, 9%, 10%, 11%, 12%, 13%, 14%, 15%, or 16% of the thickness of the microcavity.

In an exemplary embodiment of the present disclosure, the thickness of each of the red light emitting layers may be 8% to 10% of the thickness of the microcavity.

In an exemplary embodiment of the present disclosure, the thickness of the red light emitting layer in different light emitting units may be the same or different, and may be each independently selected in the range of 8% to 16% of the thickness of the microcavity.

In an exemplary embodiment of the present disclosure, the thickness of each of the red light emitting auxiliary layers may be 1% to 5% of the thickness of the microcavity. For example, the thickness of each of the red light emitting auxiliary layers may be 1%, 2%, 3%, 4%, or 5% of the thickness of the microcavity.

In an exemplary embodiment of the present disclosure, a total thickness of the red light emitting layer and the red light emitting auxiliary layer in one light emitting unit may be 9% to 17% of the thickness of the microcavity. For example, the total thickness of the red light emitting layer and the red light emitting auxiliary layer in one light emitting unit may be 9%, 10%, 11%, 12%, 13%, 14%, 15%, 16%, or 17% of the thickness of the microcavity.

The thickness of each of the red light emitting auxiliary layer is 1% to 5% of the thickness of the microcavity, and the thickness of each of the red light emitting layer is 8% to 16% of the thickness of the microcavity. In one light emitting unit, the total thickness of the red light emitting auxiliary layer and the red light emitting layer is 9% to 17% of the thickness of the microcavity, which is equivalent to the thickness of a red light emitting layer in the current OLED display substrate. Therefore, the display substrate of the embodiments of the present disclosure adopts a red light emitting auxiliary layer to replace the red light emitting layer having a certain thickness, instead of introducing an additional red light emitting auxiliary layer.

In an exemplary embodiment of the present disclosure, the thickness of each of the red light emitting auxiliary layers may be 3% to 5% of the thickness of the microcavity.

In an exemplary embodiment of the present disclosure, the thickness of the red light emitting auxiliary layer in different light emitting units may be the same or different, and may be each independently selected in the range of 1% to 5% of the thickness of the microcavity, for example, in the range of 3% to 5% of the thickness of the microcavity.

In an exemplary embodiment of the present disclosure, the second hole transport layer and the red light emitting auxiliary layer can satisfy the following conditions:

μ_{HTL-3}−μ_{HTL-2}≥1×10⁻¹@5000V^{1/2}m^{1/2}
wherein μ_{HTL-3} is the mobility of the red light emitting auxiliary layer at 5000V^{1/2}m^{1/2};
μ_{HTL-2} is the mobility of the second hole transport layer at 5000V^{1/2}m^{1/2};

When the second hole transport layer and the red light emitting auxiliary layer can satisfy μ_{HTL-3}−μ_{HTL-2}≥1×10⁻¹@5000V^{1/2}m^{1/2}, the driving voltage of the display substrate is facilitated more to be reduced.

The working voltage of the display substrate can be greatly reduced by replacing part of the red light emitting layer with the red light emitting auxiliary layer having a certain thickness and faster mobility to a certain thickness can greatly reduce. The mobility of the second hole transport layer is relatively slow, which can be matched with the mobility of the green light emitting layer of the green sub-pixel and the blue light emitting layer of the blue sub-pixel to ensure the normal transport of carriers.

In an exemplary embodiment of the present disclosure, the red light emitting auxiliary layer and the red light emitting layer can satisfy the following conditions:

$$\vert {n}_{REML} - {n}_{HTL - 3} \vert < 0.1 ;$$

wherein n_{REML} is the refractive index of the red light emitting layer;
   n_{HTL-3} is the refractive index of the red light emitting auxiliary layer.

The red light emitting auxiliary layer and the red light emitting layer can satisfy |n_{REML}−n_{HTL-3}|<0.1, that is, the refractive index of the red light emitting auxiliary layer and the red light emitting layer is at the same level, so that the microcavity structure of the display substrate can still be maintained after replacing part of the red light emitting layer with the red light emitting auxiliary layer, thereby realizing higher light extraction efficiency.

In an exemplary embodiment of the present disclosure, the red light emitting auxiliary layer and the red light emitting layer can satisfy the following conditions:

$$3 eV \leq \vert {HOMO}_{HTL - 3} \vert - \vert {LUMO}_{HTL - 3} \vert \leq 3.4 eV ;$$

$$\vert {HOMO}_{REML} \vert - \vert {HOMO}_{HTL - 3} \vert < 0.2 eV ;$$

$$\vert {LUMO}_{REML} \vert - \vert LUM {O}_{HTL - 3} \vert < 0.2 eV .$$

In the exemplary embodiment of the present disclosure, HOMO_{HTL-3} is the highest occupied molecular orbital energy level of the red light emitting auxiliary layer.

LUMO_{HTL-3} is the lowest unoccupied molecular orbital energy level of the red light emitting auxiliary layer.

HOMO_{REML} is the highest occupied molecular orbital energy level of the red light emitting layer.

LUMO_{REML} is the lowest unoccupied molecular orbital energy level of the red light emitting layer.

The red light emitting auxiliary layer and the red light emitting layer can satisfy 3 eV≤|HOMO_{HTL-3}|−|LUMO_{HTL-3}|≤3.4 eV, |HOMO_{REML}|−|HOMO_{HTL-3}|<0.2 eV, and |LUMO_{REML}|−|LUMO_{HTL-3}|<0.2 eV, which is beneficial to reducing the driving voltage of the display substrate and realizing higher light extraction efficiency.

In an exemplary embodiment of the present disclosure, the first hole transport layer, the second hole transport layer, the red light emitting auxiliary layer and the red light emitting layer can satisfy the following conditions:

$${T}_{HTL - 3} > {T}_{HTL - 2} ;$$

$${T}_{HTL - 3} < {T}_{HTL - 1} ;$$

$${T}_{HTL - 3} + {T}_{HTL - 2} \geq {T}_{HTL - 1} ;$$

$${T}_{HTL - 3} < {T}_{REML} .$$

In the exemplary embodiment of the present disclosure, T_{HTL-1} is a thickness of the first hole transport layer.

T_{HTL-2} is a thickness of the second hole transport layer.

T_{HTL-3} is a thickness of the red light emitting auxiliary layer.

T_{REML} is a thickness of the red light emitting layer.

The first hole transport layer, the second hole transport layer, the red light emitting auxiliary layer and the red light emitting layer satisfy T_{HTL-3}>T_{HTL-2}, T_{HTL-3}<T_{HTL-1}, T_{HTL-3}+T_{HTL-2}≥T_{HTL-1}, and T_{HTL-3}<T_{REML}, which is beneficial to ensuring the normal transport of carriers and effectively reducing the working voltage of the display substrate.

In an exemplary embodiment of the present disclosure, the thickness of each of the red light emitting layers may be 30 nm to 50 nm, and the thickness of each of the red light emitting auxiliary layers may be 10 nm to 25 nm.

The thickness of each of the red light emitting layers may be 30 nm to 50 nm, for example, 30 nm, 35 nm, 40 nm, 45 nm, or 50 nm.

The thickness of each of the red light emitting auxiliary layers may be 10 nm to 25 nm, for example, 10 nm, 15 nm, 20 nm, or 25 nm.

In an exemplary embodiment of the present disclosure, the display substrate may further include a green sub-pixel and a blue sub-pixel, the emitting layer further includes a green light emitting layer and a blue light emitting layer respectively located at the green sub-pixel and the blue sub-pixel, and at least one of the light emitting units may further include any one or more of a green light emitting auxiliary layer located at the green sub-pixel and a blue light emitting auxiliary layer located at the blue sub-pixel. The green light emitting auxiliary layer includes a hole transport material, and the blue light emitting auxiliary layer includes a hole transport material.

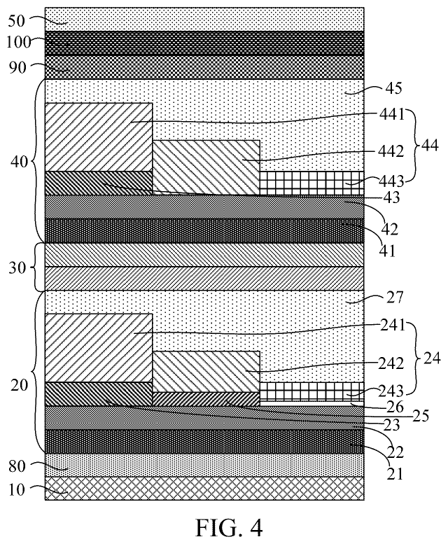

FIG. 4 is a schematic diagram of a structure of yet another display substrate provided by an exemplary embodiment of the present disclosure. As shown in FIG. 4, a green sub-pixel and a blue sub-pixel of the first emitting layer 24 are respectively provided with a first green light emitting auxiliary layer 25 located between the green light emitting layer 242 and the second hole transport layer 22, and a first blue light emitting auxiliary layer 26 located between the blue light emitting layer 243 and the second hole transport layer 22. When the red sub-pixel, the green sub-pixel and the blue sub-pixel of a light emitting unit are all provided with a light emitting auxiliary layer that replaces part of the emitting layer, the driving voltage of the display substrate is facilitated to be reduced to a greater extent.

In an exemplary embodiment of the present disclosure, the red light emitting auxiliary layer, the green light emitting layer, and the blue light emitting layer can satisfy the following conditions:

$$\vert {HOMO}_{GEML} \vert - \vert {HOMO}_{HTL - 3} \vert \geq 0.2 eV ;$$

$$\vert {HOMO}_{BEML} \vert - \vert {HOMO}_{HTL - 3} \vert \geq 0.2 eV .$$

In an exemplary embodiment of the present disclosure, HOMO_{HTL-3} is the highest occupied molecular orbital energy level of the red light emitting auxiliary layer.

HOMO_{GEML} is the highest occupied molecular orbital energy level of the green light emitting layer.

HOMO_{BEML} is the highest occupied molecular orbital energy level of the blue light emitting layer.

The red light emitting auxiliary layer, the green light emitting layer and the blue light emitting layer satisfy |HOMO_{GEML}|−|HOMO_{HTL-3}|≥0.2 eV, and |HOMO_{BEML}|−|HOMO_{HTL-3}|≥0.2 eV, which is beneficial to ensuring the normal transport of carriers and effectively reducing the working voltage of the display substrate.

In an exemplary embodiment of the present disclosure, the light emitting substrate may further include any one or more of the following layers: a hole injection layer (HIL), an electron block layer (EBL), a hole block layer (HBL), an electron transport layer (ETL), and an electron injection layer (EIL). In an exemplary embodiment of the present disclosure, one or more layers of the hole injection layer, the hole transport layer, the electron block layer, the hole block layer, the electron transport layer, and the electron injection layer of all sub-pixels may be a common layer communicated together. Emitting layers of adjacent sub-pixels may be overlapped slightly, or may be mutually isolated.

As shown in FIG. 1, the light emitting substrate further includes a hole injection layer 80 disposed between the first electrode layer 10 and the first light emitting unit 20, an electron transport layer 90 disposed on a side of the second light emitting unit 40 away from the first electrode layer 10, and an electron injection layer 100 disposed between the electron transport layer 90 and the second electrode layer 50. The first light emitting unit 20 further includes a first hole block layer 27 disposed on a side of the first emitting layer 24 away from the first electrode layer 10. The second light emitting unit 40 further includes a second hole block layer 45 disposed on a side of the second emitting layer 44 away from the first electrode layer 10.

In an exemplary embodiment of the present disclosure, the material of the anode layer may be a material with a high work function. For example, for a bottom-emission device, the anode may adopt a transparent oxide material, such as indium tin oxide (ITO) or Indium Zinc Oxide (IZO). Alternatively, for top-emission devices, the anode can adopt a composite electrode of metal and transparent oxide, such as ITO (Indium Tin Oxide)/Ag/ITO, Ag/IZO (Indium Zinc Oxide), carbon nanotubes (CNT)/ITO, CNT/IZO, Graphene Oxide (GO)/ITO, GO/IZO, Al/ITO or Al/IZO, etc., which can ensure good reflectivity.

In an exemplary embodiment of the present disclosure, a material of the hole injection layer may include transition metal oxides, for example, may include any one or more of molybdenum oxides, titanium oxides, vanadium oxides, rhenium oxides, ruthenium oxides, chromium oxides, zirconium oxides, hafnium oxides, tantalum oxides, silver oxides, tungsten oxides, and manganese oxides.

In another exemplary embodiment, the material of the hole injection layer may include a p-type dopant of a strong electron absorption system and a hole transport material.

The p-type dopant may include any one or more of 2,3,6,7,10,11-hexacyano-1,4,5,8,9,12-hexazabenzophenanthrene (HATCN), 2,3,5,6-tetrafluoro-7,7′,8,8′-tetracyano-p-benzoquinone (F4TCNQ), and 1,2,3-tris[(cyano)(4-cyano-2,3,5,6-tetrafluorophenyl)methylene]cyclopropane.

The hole transport material may include any one or more of a arylamine-based hole transport material, a dimethylfluorene-based hole transport material, and a carbazole-based hole transport material; for example, the hole transport material may include any one or more of 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′-bis(9-carbazolyl)biphenyl (CBP), and 9-phenyl-3-[4-(10-phenyl-9-anthryl)phenyl]-9H-carbazole (PCzPA).

In an exemplary embodiment of the present disclosure, the hole injection layer may be formed by evaporation; and the thickness thereof may be 5 nm to 20 nm.

In an exemplary embodiment of the present disclosure, a material of the hole transport layer may include any one or more of an arylamine-based hole transport material, a dimethylfluorene-based hole transport material, and a carbazole-based hole transport material; for example, the material of the hole transport layer may include any one or more of 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl)triphenylamine (BAFLP), and 4,4′-bis[N-(9,9-dimethylfluoren-2-yl)-N-phenylamino]biphenyl (DFLDPBi).

In an exemplary embodiment of the present disclosure, the material of the red light emitting auxiliary layer may include any one or more of an arylamine-based hole transport material, a carbazole-based hole transport material, and a dimethylfluorene-based hole transport material. For example, the material of the red light emitting auxiliary layer may be 4,4′-bis(9-carbazolyl)biphenyl (CBP), 9-phenyl-3-[4-(10-phenyl-9-anthryl)phenyl]-9H-carbazole (PCzPA), etc.

In an exemplary embodiment of the present disclosure, the material of the green light emitting auxiliary layer may include any one or more of an arylamine-based hole transport material, a carbazole-based hole transport material, and a dimethylfluorene-based hole transport material. For example, the material of the green light emitting auxiliary layer may be 3,3′-bis(9H-carbazol-9-yl)-1,1′-bicarbazole (m-CBP), etc.

In an exemplary embodiment of the present disclosure, the material of the blue light emitting auxiliary layer may include any one or more of an arylamine-based hole transport material, a carbazole-based hole transport material, and a dimethylfluorene-based hole transport material. For example, the material of the blue light emitting auxiliary layer may be 1,3-dicarbazol-9-yl benzene (mCP), etc.

In an exemplary embodiment of the present disclosure, the hole transport layer may be formed by evaporation.

In an exemplary embodiment of the present disclosure, a material of the emitting layer may include one luminescent material, or may also include two or more luminescent materials. For example, a host luminescent material and a guest luminescent material doped into the host luminescent material may be included.

In an exemplary embodiment of the present disclosure, the red light emitting layer may include a red host material and a red guest material, a doping ratio of the red guest material is 1% to 5%, for example, may be 2% to 3%. The red host material may be a red phosphorescent material, and the red guest material may be a red phosphorescent dopant.

In an exemplary embodiment of the present disclosure, the red host material may include any one or more of a DCM-series red luminescent material, and the red guest material may include any one or more of a metal complex-based red luminescent material.

For example, the red host material may be any one or more of 4-(dicyanomethylene)-2-methyl-6-(4-dimethylaminostyryl)-4H-pyran (DCM), 4-(dicyanomethylene)-2-tert-butyl-6-(1,1,7,7-tetramethyljulolidyl-9-enyl)-4H-pyran (DCJTB), and DCJIT; and the red guest material may be any one or more of di(1-phenylisoquinoline)(acetylacetone)iridium(III) (Ir(piq)₂(acac)), octaethylporphyrin platinum (PtOEP), and di(2-(2′-benzothiophenyl)pyridine-N,C3′) (acetylacetone)iridium (Ir(btp)₂(acac)).

In an exemplary embodiment of the present disclosure, the green light emitting layer may include a green host material and a green guest material, and a doping ratio of the green guest material may be 5% to 15%, such as 8% to 10%. The green host material can be a green phosphorescent material, and the green guest material can be a green phosphorescent dopant. Alternatively, the green host material may be a green fluorescent material, and the green guest material may be a green fluorescent dopant.

In an exemplary embodiment of the present disclosure, the green host material may include any one or more of a coumarin dye, a quinacridone derivative-based green luminescent material, a polycyclic aromatic hydrocarbon-based green luminescent material, a diamine anthracene derivative-based green luminescent material, and a carbazole derivative-based green luminescent material, and the green guest material may include any one or more of a metal complex-based green luminescent material.

For example, the green host material may include coumarin 6 (C-6), coumarin 545T (C-525T), quinacridone (QA), N,N″-dimethylquinacridone (DMQA), 5,12-diphenylnaphthacene (DPT), N10,N10′-diphenyl-N10,N10′-dinaphthalenyl-9,9′-bianthracene-10,10′-diamine (BA-NPB), tris(8-hydroxyquinoline)aluminum (III) (Alq3), etc.; and the green host material may be any one or more of tris(2-phenylpyridine)iridium(Ir(ppy)₃), and acetylpyruvate bis(2-phenylpyridine)iridium(Ir(ppy)₂(acac)).

In an exemplary embodiment of the present disclosure, the blue light emitting layer may include a blue host material and a blue guest material, a doping ratio of the blue guest material is 1% to 5%, for example, may be 1% to 3%.

In an exemplary embodiment of the present disclosure, the blue host material may include any one or more of a pyrene derivative-based blue luminescent material, an anthracene derivative-based blue luminescent material, a fluorene derivative-based blue luminescent material, a perylene derivative-based blue luminescent material, and a styrylamine derivative-based blue luminescent material, and the guest material may include any one or more of a metal complex-based blue luminescent material.

For example, the blue host material may be N1,N6-bis([1,1′-biphenyl]-2-yl)-N1,N6-bis([1,1′-biphenyl]-4-yl) pyrene-1,6-diamine, 9,10-di-(2-naphthyl) anthracene (ADN), 2-methyl-9,10-di-2-naphthyl anthracene (MADN), etc.; and the blue guest material may be any one or more of 2,5,8,11-tetra-tert-butylperylene (TBPe), 4,4′-bis[4-(diphenylamino)styryl]biphenyl (BDAVBi), 4,4′-bis[4-(di-p-tolylamino)styryl]biphenyl (DPAVBi), and bis(4,6-difluorophenylpyridine-C2,N)pyridine formyl iridium(FIrpic).

In an exemplary embodiment of the present disclosure, the emitting layer may be formed by evaporation.

In an exemplary embodiment of the present disclosure, the charge generation layer may include a P-type charge generation layer and an N-type charge generation layer. The P-type charge generation layer may be a hole-type material such as NPB, TPD, etc., and the N-type charge generation layer may be an electron-type material containing phenanthroline or phosphoryl group. Both the P-type charge generation layer and the N-type charge generation layer may contain a dopant. The dopant of the P-type charge generation layer may be HATCN, F4TCNQ, etc., and the dopant of the N-type charge generation layer may be alkali metal or alkaline earth metal and their oxides.

In an exemplary embodiment of the present disclosure, the material of the hole block layer may include an aromatic heterocycle-based hole block material, for example, any one or more of a benzimidazole derivative-based hole block material, an imidazopyridine derivative-based hole block material, a benzimidazophenanthridine derivative-based hole block material, a pyrimidine derivative-based hole block material, a triazine derivative-based hole block material, a quinoline derivative-based hole block material, an isoquinoline derivative-based hole block material, and a phenanthroline derivative-based hole block material.

For another example, the material of the hole block layer may include any one or more of 2-(4-biphenyl)-5-(4-tert-butylphenyl)-1,3,4-oxadiazole (PBD), 1,3-bis[5-(p-tert-butylphenyl)-1,3,4-oxadiazole-2-yl]benzene (OXD-7), 3-(4-tert-butylphenyl)-4-phenyl-5-(4-biphenyl)-1,2,4-triazole (TAZ), 3-(4-tert-butylphenyl)-4-(4-ethylphenyl)-5-(4-biphenyl)-1,2,4-triazole (p-EtTAZ), red phenanthroline (BPhen), BCP, and 4,4′-bis(5-methylbenzoxazol-2-yl)stilbene (BzOs).

In an exemplary embodiment of the present disclosure, the hole block layer may be formed by evaporation.

In an exemplary embodiment of the present disclosure, the material of the electron transport layer may include an aromatic heterocycle-based electron transport material, for example, any one or more of a benzimidazole derivative-based electron transport material, an imidazopyridine derivative-based electron transport material, a benzimidazophenanthridine derivative-based electron transport material, a pyrimidine derivative-based electron transport material, a triazine derivative-based electron transport material, a quinoline derivative-based electron transport material, an isoquinoline derivative-based electron transport material, and a phenanthroline derivative-based electron transport material.

For another example, the material of the electron transport layer may include any one or more of 2-(4-biphenyl)-5-(4-tert-butylphenyl)-1,3,4-oxadiazole (PBD), 1,3-bis[5-(p-tert-butylphenyl)-1,3,4-oxadiazole-2-yl]benzene (OXD-7), 3-(4-tert-butylphenyl)-4-phenyl-5-(4-biphenyl)-1,2,4-triazole (TAZ), 3-(4-tert-butylphenyl)-4-(4-ethylphenyl)-5-(4-biphenyl)-1,2,4-triazole (p-EtTAZ), red phenanthroline (BPhen), BCP, and 4,4′-bis(5-methylbenzoxazol-2-yl)stilbene (BzOs).

In an exemplary embodiment of the present disclosure, the electron transport layer may be formed by evaporation.

In an exemplary embodiment of the present disclosure, the material of the electron injection layer may include any one or more of an alkali metal electron injection material and a metal electron injection material.

For example, the material of the electron injection layer may include any one or more of LiF, Yb, Mg, and Ca.

In an exemplary embodiment of the present disclosure, the electron injection layer may be formed by evaporation.

In an exemplary embodiment of the present disclosure, the cathode may be formed by the metal with relatively low work function, such as Al, Ag, and Mg, or formed by an alloy containing a metal material with low work function.

An embodiment of the present disclosure also provides a display apparatus, including the display substrate as provided in the above embodiment of the present disclosure.

The display apparatus may be any product or component with a display function, such as a mobile phone, a tablet computer, a television, a display, a laptop computer, a digital photo frame, a navigator, a vehicle-mounted display, a smart watch, and a smart bracelet.

An embodiment of the present disclosure also provides a method for manufacturing the display substrate as provided in the above embodiment of the present disclosure. The manufacturing method includes the following steps:
forming a first electrode layer on a side of a substrate;
forming a first hole transport layer and a second hole transport layer sequentially on a side of the first electrode layer away from the substrate;
forming a red light emitting auxiliary layer located at a red sub-pixel on a side of the second hole transport layer away from the substrate;
forming a red light emitting layer located at a red sub-pixel on a side of the red light emitting auxiliary layer away from the substrate; and forming a green light emitting layer and a blue light emitting layer respectively located at a green sub-pixel and a blue sub-pixel on a side of the second hole transport layer away from the substrate, wherein an emitting layer is constituted by the red light emitting layer, the green light emitting layer and the blue light emitting layer, and one light emitting unit is constituted by the emitting layer, the red light emitting auxiliary layer, the first hole transport layer and the second hole transport layer;
forming a charge generation layer on a side of the light emitting unit away from the substrate;
forming at least one light emitting unit on a side of the charge generation layer away from the substrate, and forming a charge generation layer between two adjacent light emitting units;
and forming a second electrode layer.

In an exemplary embodiment of the present disclosure, the method for forming the first hole transport layer and the second hole transport layer may be an evaporation method.

In an exemplary embodiment of the present disclosure, the method for forming the red light emitting auxiliary layer may be an evaporation method.

In an exemplary embodiment of the present disclosure, the method for forming the red light emitting layer, the green light emitting layer and the blue light emitting layer may be an evaporation method.

The embodiment of the disclosure also provides a method for reducing a driving voltage of a display substrate. The display substrate includes a red sub-pixel and further includes: a first electrode layer, a second electrode layer, a plurality of light emitting units disposed between the first electrode layer and the second electrode layer and connected in series, and a charge generation layer disposed between two adjacent light emitting units. A microcavity is formed between the first electrode layer and the second electrode layer. The light emitting units include a first hole transport layer, a second hole transport layer and an emitting layer. The emitting layer includes a red light emitting layer located at the red sub-pixel.

The method for reducing the driving voltage of the display substrate includes: forming a red light emitting auxiliary layer located at the red sub-pixel by adopting a hole transport material between the red light emitting layer and the second hole transport layer, and the thickness of the red light emitting layer is 8% to 16% of the thickness of the microcavity, the thickness of the red light emitting auxiliary layer is 1% to 5% of the thickness of the microcavity, and a total thickness of the red light emitting layer and the red light emitting auxiliary layer in one light emitting unit is 9% to 17% of the thickness of the microcavity.

The application of the schemes of the embodiments of the present disclosure in reducing the driving voltage of an organic EL device is explained below by exemplary embodiments.

The structure of an EL device is shown in FIG. 1. The EL device includes: an indium tin oxide ITO layer formed on a glass substrate and used as an anode, a hole injection layer HTL (5 nm to 30 nm), a first hole transport layer HTL-1 (15 nm to 25 nm), a second hole transport layer HTL-2 (5 nm to 15 nm), a first red light emitting auxiliary layer HTL-3 (10 nm to 25 nm), a first red light emitting layer REML-1 (30 nm to 50 nm), a first green light emitting layer GEML-1 (30 nm to 50 nm), a first blue light emitting layer BEML-1 (10 nm to 20 nm), a first hole block layer HBL-1 (5 nm to 15 nm), N-CGL (15 nm to 25 nm), P-CGL (5 nm to 15 nm), a third hole transport layer HTL-4 (15 nm to 25 nm), a fourth hole transport layer HTL-5 (5 nm to 15 nm), a second red light emitting auxiliary layer HTL-6 (10 nm to 25 nm), a second red light emitting layer REML-2 (30 nm to 50 nm), a second green light emitting layer GEML-2 (30 nm to 50 nm), a second blue light emitting layer BEML-2 (10 nm to 20 nm), a second hole block layer HBL-2 (5 nm to 15 nm), an electron transport layer ETL (20 nm to 100 nm), an electron injection layer EIL (1 nm to 10 nm), and a cathode (10 nm to 20 nm). Furthermore, the structures of the two light emitting units are identical, that is, HTL-1 and HTL-4, HTL-2 and HTL-5, HTL-3 and HTL-6, HBL-1 and HBL-2 are identical. Parameters including materials, doping ratio, film thickness, etc. are the same.

The device structure of Example 1 includes: ITO/HIL (10 nm)/HTL-1 (19 nm)/HTL-2 (10 nm)/HTL-3 (17 nm)/RH:RD (3 wt %, 42 nm); GH:GD (10 wt %, 40 nm); BH:BD (3 wt %, 15 nm)/HBL-1 (5 nm)/N-CGL (1% Li, nm)/P-CGL (5%, 9 nm)/HTL-4 (19 nm)/HTL-5 (10 nm)/HTL-6 (17 nm)/RH:RD (3 wt %, 42 nm); GH:GD (10 wt %, 40 nm); BH:BD (3 wt %, 15 nm)/HBL-2 (5 nm)/ETL:LIQ (1:1, 35 nm)/EIL (1 nm)/cathode (15 nm).

Other Examples and Comparative Examples differ from Example 1 only in that: the thickness of the first red light emitting auxiliary layer HTL-3 (or the second red light emitting auxiliary layer HTL-6) is different, and the thickness of the first red light emitting layer REML-1 (or the second red light emitting layer REML-2) is different.

The preparation process of the device includes the following steps:
S10: A glass substrate with ITO is ultrasonically treated in a cleaning agent, rinsed in deionized water, ultrasonically degreased in an acetone-ethanol mixed solvent, and baked in a clean environment until water is completely removed.
S20: The above glass substrate with an anode is placed in a vacuum chamber, evacuated to 1×10⁵ Pa to 1×10⁶ Pa, and a hole injection material and a first hole transport material (the doping ratio of the first hole transport material is 5%) is vacuum co-evaporated on a film of the anode layer to form a hole injection layer.
S30: A first hole transport material is evaporated on the hole injection layer to form a first hole transport layer.
S40: A second hole transport layer material is evaporated on the first hole transport layer to form a second hole transport layer.
S50: A first red light emitting auxiliary layer (a third hole transport layer material) is evaporated in the red sub-pixel region on the second hole transport layer, to form a first red light emitting auxiliary layer.
S60: A first red light emitting layer, a first green light emitting layer and a first blue light emitting layer are evaporated in the red sub-pixel region, the green sub-pixel region and the blue sub-pixel region respectively to form a first emitting layer.
S70: A first hole block layer of the device is vacuum evaporated on the first emitting layer.
S80: N-CGL with a Li doping ratio of 1 wt %, N-CGL with a Li doping ratio of 1 wt % and P-CGL with a Li doping ratio of 5 wt % are sequentially deposited on the first hole block layer to form a charge generation layer.
S90: A first hole transport material is evaporated on the charge generation layer to form a third hole transport layer.
S100: A second hole transport layer material is evaporated on the third hole transport layer to form a fourth hole transport layer.
S110: A second red light emitting auxiliary layer (a third hole transport layer material) is evaporated in the red sub-pixel region on the fourth hole transport layer, to form a second red light emitting auxiliary layer.
S120: A second red light emitting layer, a second green light emitting layer and a second blue light emitting layer are evaporated in the red sub-pixel region, the green sub-pixel region and the blue sub-pixel region respectively to form a second emitting layer.
S130: A second hole block layer of the device is vacuum evaporated on the second emitting layer.
S140: An electron transport layer of the device is vacuum evaporated on the second hole block layer.
S150: Yb with a thickness of 1 nm is vacuum evaporated on the electron transport layer as an electron injection layer.
S160: Mg:Ag (1:9) layer is evaporated on the electron injection layer as the cathode of the device.

The raw materials used in the above Examples and Comparative Examples are as follows:

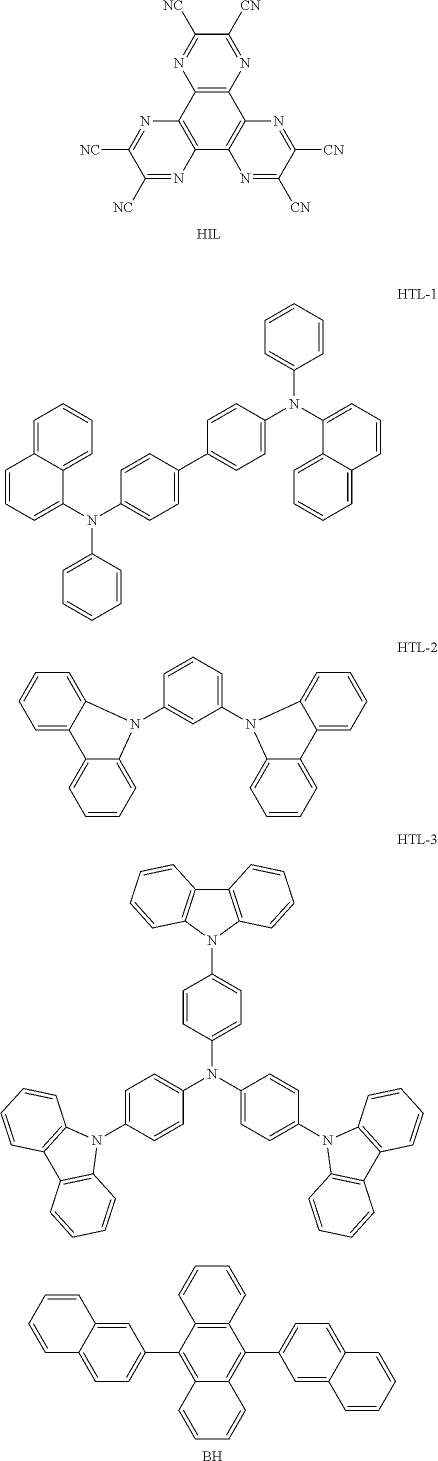

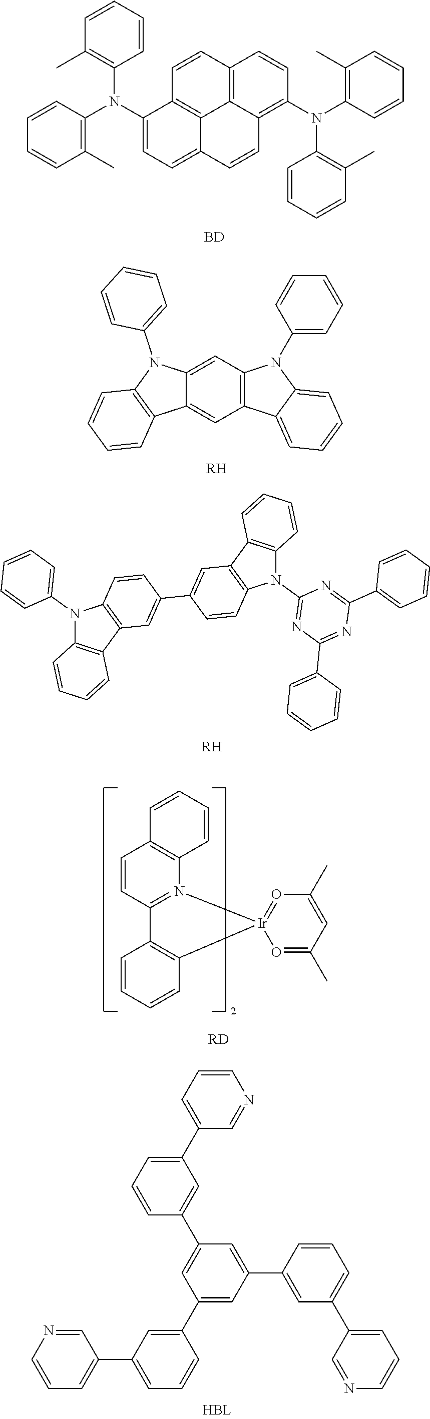

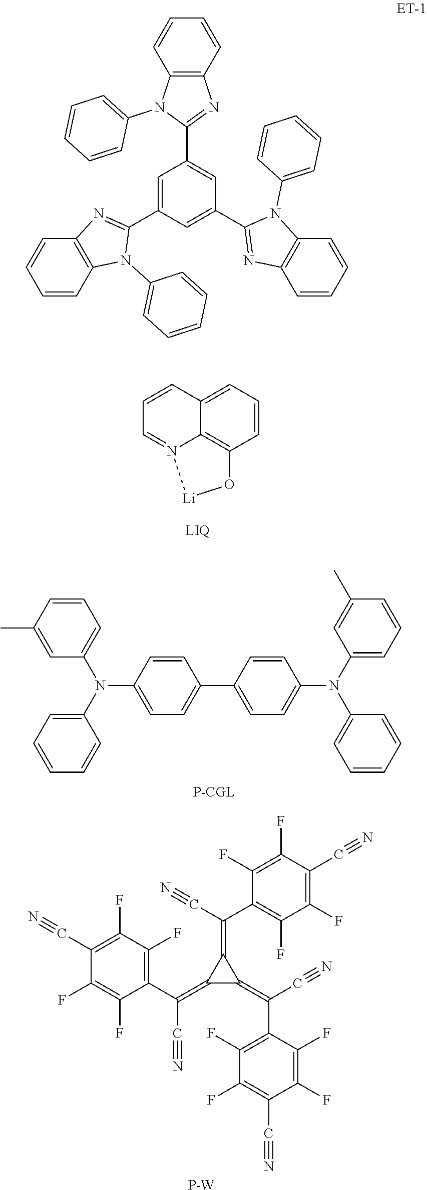

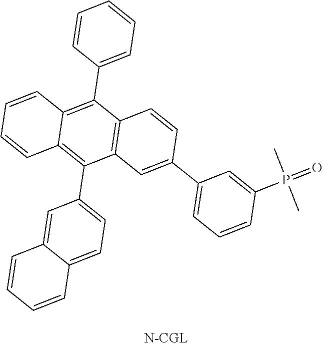 [SMILES: CP(C)(=O)c1cccc(-c2ccc3c(-c4ccccc4)c4ccccc4c(-c4ccc5ccccc5c4)c3c2)c1]

### Metal Li: N-W

The driving voltages and light emitting efficiencies of the EL devices of the above Examples and Comparative Examples are shown in Table 1.

TABLE 1
Driving Voltage and Light Emitting Efficiency of EL Devices

| | HTL-3/HTL-6 | | RH:RD | | | Service |
|---|---|---|---|---|---|---|
| | Thickness | | Thickness | Voltage | Efficiency | Life |
| Example 1 | 20 | nm | 42 nm | 90% | 96% | 102% |
| Example 2 | 10 | nm | 50 nm | 93% | 97% | 105% |
| Comparative | 0 | nm | 60 nm | 100% | 100% | 100% |
| Example 1 | | | | | | |
| Comparative | 30 | nm | 30 nm | 97% | 90% | 98% |
| Example 2 | | | | | | |
| Comparative | 40 | nm | 20 nm | 98% | 85% | 99% |
| Example 3 | | | | | | |

It can be seen that, by adopting a red light emitting auxiliary layer to replace the red light emitting layer having a certain thickness, the device of the exemplary embodiments of the present disclosure can reduce the driving voltage of the EL device and maintain the light emitting efficiency of the EL device substantially unchanged.

Although the implementations of the present disclosure are disclosed above, the contents are only implementations used for ease of understanding of the present disclosure, but not intended to limit the present disclosure. Those skilled in the art may make any modification and change in the forms and details of the implementations without departing from the essence and scope of the present disclosure. However, the scope of protection of the present disclosure should still be subject to the scope defined by the attached claims.

1. A display substrate, comprising a red sub-pixel, and further comprising: a first electrode layer, a second electrode layer, a plurality of light emitting units disposed between the first electrode layer and the second electrode layer and connected in series, and a charge generation layer disposed between two adjacent light emitting units, wherein a microcavity is formed between the first electrode layer and the second electrode layer; the light emitting units comprise a first hole transport layer, a second hole transport layer and an emitting layer, the emitting layer comprises a red light emitting layer located at the red sub-pixel, at least one of the light emitting units further comprises a red light emitting auxiliary layer located at the red sub-pixel, the red light emitting auxiliary layer is disposed between the red light emitting layer and the second hole transport layer, and the red light emitting auxiliary layer comprises a hole transport material;
wherein a thickness of each of the red light emitting layers is 8% to 16% of a thickness of the microcavity.

2. The display substrate according to claim 1, wherein the thickness of each of the red light emitting layers is 8% to 10% of the thickness of the microcavity.

3. The display substrate according to claim 1, wherein a thickness of each of the red light emitting auxiliary layers is 1% to 5% of the thickness of the microcavity.

4. The display substrate according to claim 3, wherein the thickness of each of the red light emitting auxiliary layers is 3% to 5% of the thickness of the microcavity.

5. The display substrate according to claim 1, wherein a total thickness of the red light emitting layer and the red light emitting auxiliary layer in one light emitting unit is 9% to 17% of the thickness of the microcavity.

6. The display substrate according to claim 5, wherein the second hole transport layer and the red light emitting auxiliary layer satisfy the following conditions:
μ_{HTL-3}−μ_{HTL-2}≥1×10⁻¹@5000V^{1/2}m^{1/2},
wherein μ_{HTL-3} is the mobility of the red light emitting auxiliary layer at 5000V^{1/2}m^{1/2},
μ_{HTL-2} is the mobility of the second hole transport layer at 5000V^{1/2}m^{1/2}.

7. The display substrate according to claim 6, wherein the red light emitting auxiliary layer and the red light emitting layer satisfy the following conditions:
$$\vert {n}_{REML} - {n}_{HTL - 3} \vert < 0.1 ;$$
wherein n_{REML} is the refractive index of the red light emitting layer;
n_{HTL-3} is the refractive index of the red light emitting auxiliary layer.

8. The display substrate according to claim 6, wherein the red light emitting auxiliary layer and the red light emitting layer satisfy the following conditions:
$$3 eV \leq \vert {HOMO}_{HTL - 3} \vert - \vert {LUMO}_{HTL - 3} \vert \leq 3.4 eV ;$$
$$\vert {HOMO}_{REML} \vert - \vert {HOMO}_{HTL - 3} \vert < 0.2 eV ;$$
$$\vert {LUMO}_{REML} \vert - \vert LUM {O}_{HTL - 3} \vert < 0.2 eV ;$$
wherein HOMO_{HTL-3} is the highest occupied molecular orbital energy level of the red light emitting auxiliary layer;
LUMO_{HTL-3} is the lowest unoccupied molecular orbital energy level of the red light emitting auxiliary layer;
HOMO_{REML} is the highest occupied molecular orbital energy level of the red light emitting layer; and
LUMO_{REML} is the lowest unoccupied molecular orbital energy level of the red light emitting layer.

9. The display substrate according to claim 6, wherein the first hole transport layer, the second hole transport layer, the red light emitting auxiliary layer and the red light emitting layer satisfy the following conditions:
$${T}_{HTL - 3} > {T}_{HTL - 2} ;$$
$${T}_{HTL - 3} < {T}_{HTL - 1} ;$$
$${T}_{HTL - 3} + {T}_{HTL - 2} \geq {T}_{HTL - 1} ;$$
$${T}_{HTL - 3} < {T}_{REML} ;$$
wherein T_{HIL-1} is a thickness of the first hole transport layer;
T_{HTL-2} is a thickness of the second hole transport layer;
T_{HTL-3} is a thickness of the red light emitting auxiliary layer;
T_{REML} is a thickness of the red light emitting layer.

10. The display substrate according to claim 9, wherein each of the red light emitting layers has a thickness of 30 nm to 50 nm, and each of the red light emitting auxiliary layers has a thickness of 10 nm to 25 nm.

11. The display substrate according to claim 6, further comprising a green sub-pixel and a blue sub-pixel, wherein the emitting layer further comprises a green light emitting layer and a blue light emitting layer respectively located at the green sub-pixel and the blue sub-pixel, and at least one of the light emitting units further comprises any one or more of a green light emitting auxiliary layer located at the green sub-pixel and a blue light emitting auxiliary layer located at the blue sub-pixel; the green light emitting auxiliary layer comprises a hole transport material, and the blue light emitting auxiliary layer comprises a hole transport material.

12. The display substrate according to claim 11, wherein the red light emitting auxiliary layer, the green light emitting layer, and the blue light emitting layer satisfy the following conditions:
$$\vert {HOMO}_{GEML} \vert - \vert {HOMO}_{HTL - 3} \vert \geq 0.2 eV ;$$
$$\vert {HOMO}_{BEML} \vert - \vert {HOMO}_{HTL - 3} \vert \geq 0.2 eV ;$$
wherein HOMO_{HTL-3} is the highest occupied molecular orbital energy level of the red light emitting auxiliary layer;
HOMO_{GEML} is the highest occupied molecular orbital energy level of the green light emitting layer;
HOMO_{BEML} is the highest occupied molecular orbital energy level of the blue light emitting layer.

13. The display substrate according to claim 12, wherein the hole transport materials in the red light emitting auxiliary layer, the green light emitting auxiliary layer, and the blue light emitting auxiliary layer are each independently selected from any one or more of an arylamine-based hole transport material, a carbazole-based hole transport material, and a dimethylfluorene-based hole transport material.

14. The display substrate according to claim 13, wherein the red light emitting layer comprises a red host material and a red guest material, and a doping ratio of the red guest material is 1% to 5%;
the red host material comprises any one or more of a DCM-series red luminescent material, and the red guest material comprises any one or more of a metal complex-based red luminescent material.

15. The display substrate according to claim 13, wherein the green light emitting layer comprises a green host material and a green guest material, and a doping ratio of the green guest material is 5% to 15%;
the green host material comprises any one or more of a coumarin dye, a quinacridone derivative-based green luminescent material, a polycyclic aromatic hydrocarbon-based green luminescent material, a diamine anthracene derivative-based green luminescent material, and a carbazole derivative-based green luminescent material, and the green guest material comprises any one or more of a metal complex-based green luminescent material.

16. The display substrate according to claim 13, wherein the blue light emitting layer comprises a blue host material and a blue guest material, and a doping ratio of the blue guest material is 1% to 5%;
the blue host material comprises any one or more of a pyrene derivative-based blue luminescent material, an anthracene derivative-based blue luminescent material, a fluorene derivative-based blue luminescent material, a perylene derivative-based blue luminescent material, and a styrylamine derivative-based blue luminescent material, and the blue guest material comprises any one or more of a metal complex-based blue luminescent material.

17. A display apparatus, comprising a display substrate according to claim 1.

18. A method for manufacturing a display substrate according to claim 1, comprising:
forming a first electrode layer on a side of a substrate;
forming a first hole transport layer and a second hole transport layer sequentially on a side of the first electrode layer away from the substrate;
forming a red light emitting auxiliary layer located at a red sub-pixel through an evaporation method on a side of the second hole transport layer away from the substrate;
forming a red light emitting layer located at a red sub-pixel through an evaporation method on a side of the red light emitting auxiliary layer away from the substrate; and forming a green light emitting layer and a blue light emitting layer respectively located at a green sub-pixel and a blue sub-pixel on a side of the second hole transport layer away from the substrate, wherein an emitting layer is constituted by the red light emitting layer, the green light emitting layer and the blue light emitting layer, and one light emitting unit is constituted by the emitting layer, the red light emitting auxiliary layer, the first hole transport layer and the second hole transport layer;
forming a charge generation layer on a side of the light emitting unit away from the substrate;
forming at least one light emitting unit on a side of the charge generation layer away from the substrate, and forming a charge generation layer between two adjacent light emitting units; and
forming a second electrode layer.

19. A method for reducing a driving voltage of a display substrate, wherein, the display substrate comprises a red sub-pixel and further comprises: a first electrode layer, a second electrode layer, a plurality of light emitting units disposed between the first electrode layer and the second electrode layer and connected in series, and a charge generation layer disposed between two adjacent light emitting units, wherein a microcavity is formed between the first electrode layer and the second electrode layer; the light emitting units comprise a first hole transport layer, a second hole transport layer and an emitting layer, the emitting layer comprises a red light emitting layer located at the red sub-pixel;
the method comprises: forming a red light emitting auxiliary layer located at the red sub-pixel by adopting a hole transport material between the red light emitting layer and the second hole transport layer, wherein the thickness of the red light emitting layer is 8% to 16% of the thickness of the microcavity, the thickness of the red light emitting auxiliary layer is 1% to 5% of the thickness of the microcavity, and a total thickness of the red light emitting layer and the red light emitting auxiliary layer in one light emitting unit is 9% to 17% of the thickness of the microcavity.
